(19) United States
(12) Patent Application Publication
(10) Pub. No.: US 2025/0349789 A1
(43) Pub. Date: Nov. 13, 2025

(54) BONDING METHOD AND BONDING APPARATUS

(71) Applicant: Tokyo Electron Limited, Tokyo (JP)

(72) Inventors: Yuki KIKUCHI, Nirasaki City (JP); Hajime NAKABAYASHI, Nirasaki City (JP)

(21) Appl. No.: 19/280,605

(22) Filed: Jul. 25, 2025

Related U.S. Application Data
(63) Continuation of application No. PCT/JP2024/000547, filed on Jan. 12, 2024.

(30) Foreign Application Priority Data
Jan. 26, 2023 (JP) 2023-010560

(51) Int. Cl. H01L 23/00; H01L 25/07

(52) U.S. Cl. CPC H01L 24/80; H01L 24/74; H01L 24/05; H01L 24/08; H01L 25/074; H01L 2224/05624; H01L 2224/05639; H01L 2224/05644; H01L 2224/05647; H01L 2224/08145; H01L 2224/74; H01L 2224/80004; H01L 2224/80011; H01L 2224/80203; H01L 2224/80895; H01L 2224/80896

(57) ABSTRACT

A bonding method includes: preparing first and second substrates, a surface of each of the first and second substrates having a first region from which an insulating film is exposed and a second region from which a conductive film is exposed, and at least one of the first or second substrate; performing a surface activation treatment on the insulating film exposed from the first region of each of the substrates; after the surface activation treatment, performing a hydrophilization treatment on a surface of the insulating film exposed from the first region by supplying a hydrophilization treatment liquid to the surfaces of the substrates; after the surface activation treatment, and before the hydrophilization treatment or parallel to the hydrophilization treatment, supplying an ionic surfactant to the surface of the at least one of the first or second substrate; and bonding the surfaces of the substrates after the hydrophilization treatment.

### CROSS-REFERENCE TO RELATED APPLICATIONS

This application is a bypass continuation application of International Application No. PCT/JP2024/000547 having an international filing date of Jan. 12, 2024 and designating the United States, the international application being based upon and claiming the benefit of priority from Japanese Patent Application No. 2023-010560, filed on Jan. 26, 2023, the entire contents of which are incorporated herein by reference.

### TECHNICAL FIELD

The present disclosure relates to a bonding method and a bonding apparatus.

### BACKGROUND

Patent Document 1 discloses a technique for bonding substrates having insulating films and conductive films formed on surfaces of the substrates as a three-dimensional integration technique for three-dimensionally stacking semiconductor devices one above another.

### PRIOR ART DOCUMENT

### Patent Document

Patent Document 1: Japanese Laid-Open Patent Publication No. 2012-049267

### SUMMARY

According to one embodiment of the present disclosure, a bonding method includes: preparing a first substrate and a second substrate, a surface of each of the first substrate and the second substrate having a first region from which an insulating film is exposed and a second region from which a conductive film is exposed, and at least one of the first substrate or the second substrate having a PN junction; performing a surface activation treatment on the insulating film exposed from the first region of each of the first substrate and the second substrate; after the surface activation treatment, performing a hydrophilization treatment on a surface of the insulating film exposed from the first region by supplying a hydrophilization treatment liquid to the surfaces of the first substrate and the second substrate; after the surface activation treatment, and before the hydrophilization treatment or parallel to the hydrophilization treatment, supplying an ionic surfactant to the surface of the at least one of the first substrate or the second substrate, which has the PN junction; and bonding the surface of the first substrate and the surface of the second substrate after the hydrophilization treatment.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a flowchart for explaining a bonding method according to an embodiment.

FIG. 2 is a cross-sectional view illustrating an example of a first substrate used in the bonding method of FIG. 1.

FIG. 3 is a cross-sectional view illustrating an example of a second substrate used in the bonding method of FIG. 1.

FIGS. 4A and 4B are diagrams for explaining a surface state of an insulating film when performing a surface activation treatment.

FIG. 5 is a diagram for explaining a surface state of an insulating film when performing a hydrophilization treatment.

FIGS. 6A and 6B are diagrams for explaining effects when using CO₂ water as a hydrophilization treatment liquid.

FIG. 7 is a diagram for explaining a mechanism by which a metal is precipitated on an electrode pad connected to an N-type portion when a PN junction presents in an electronic circuit element in a substrate.

FIG. 8 is a diagram for explaining a mechanism by which a metal is suppressed from being precipitated on an electrode pad connected to an N-type portion by supplying a cationic surfactant as an ionic surfactant prior to supplying a hydrophilization treatment liquid when a PN junction presents in an electronic circuit element in a substrate.

FIG. 9 is a diagram for explaining a mechanism by which a metal is suppressed from being precipitated on an electrode pad connected to an N-type portion by supplying an anionic surfactant as an ionic surfactant prior to supplying a hydrophilization treatment liquid when a PN junction presents in an electronic circuit element in a substrate.

FIG. 10 is a cross-sectional view illustrating a state in which the first substrate and the second substrate are aligned in a process of bonding the first substrate and the second substrate.

FIG. 11 is a cross-sectional view illustrating a state in which the first substrate and the second substrate are bonded to each other in a compression manner in the process of bonding the first substrate and the second substrate.

FIGS. 12A and 12B are diagrams for explaining a reaction of the surface of the insulating film when performing the process of bonding the first substrate and the second substrate.

FIG. 13 is a transverse cross-sectional view illustrating an example of a bonding apparatus for performing the bonding method according to an embodiment.

FIG. 14 is a longitudinal cross-sectional view illustrating an example of the bonding apparatus for performing the bonding method according to an embodiment.

FIG. 15 is a diagram for explaining an activation treater in the bonding apparatus.

FIG. 16 is a diagram for explaining an ionic surfactant supply and a hydrophilization treatment liquid supply in the bonding apparatus.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### <History>

In recent years, along with the miniaturization and three-dimensionalization of VLSI (Very Large-Scale Integration), attention has been paid to a three-dimension (3D) stacking technique in which electronic circuit elements presenting in different substrates, which are separately fabricated, are directly bonded to each other to produce a single electronic circuit element. In particular, a hybrid bonding in which an insulating film and a conductive film presenting in one substrate are simultaneously bonded to an insulating film and a conductive film presenting in another substrate, respectively, and the substrates are compressed against each other, has been attracting attention as a technique for further increasing a speed of VLSI and reducing a power consumption of VLSI. The conductive film is, for example, an electrode pad, and is used for inputting and outputting electrical signals.

In the hybrid bonding, a single element may be formed by bonding two substrates having different permissible thermal budgets (e.g., different kinds of substrates such as a Si substrate obtained by vertically three-dimensional stacking a N-channel (Nch) transistor circuit and a P-channel (Pch) transistor circuit of a C-FET (Complementary-Field Effect Transistor) on the Si substrate and a Ge or III-V group of substrate) after forming electronic circuit elements on the substrates. The hybrid bonding eliminates a need for signal communication between low-impedance input/output circuits formed on the different substrates. This dramatically increases the speed of the signal transmission between the electronic circuit elements formed on the substrates.

In such a hybrid bonding technique, the conductive films are simply bonded to each other by heat and pressure, while the insulating films needs to be subjected to a pretreatment in which surfaces thereof are OH-terminated to become hydrophilic before the insulating films are bonded to each other. The pretreatment may include a process of forming a dangling bond by activating the surfaces of the insulating films with plasma or the like, and a process of supplying a hydrophilization treatment liquid such as pure water to the surfaces of the insulating films.

However, when a PN junction presents in an electronic circuit element in a substrate, for example, when a P-channel and an N-well, which is an N-type portion, are bonded to each other, electromotive force is generated. Then, when metal ions (for example, Cu ions) in one conductive film (electrode pad) are dissolved into the hydrophilization treatment liquid presenting in the surface of the substrate, it has been found that Cu is precipitated on one conductive film (electrode pad) connected to the N-well via a wiring due to electrolytic plating reaction. When Cu is precipitated on one conductive film (electrode pad) in this way, it may come into contact with Cu precipitated on adjacent conductive film (electrode pad) so that they may be short-circuited.

Therefore, in an embodiment, a process of supplying an ionic surfactant to the surface of the substrate is performed prior to the process of supplying the hydrophilization treatment liquid or parallel to the process of supplying the hydrophilization treatment liquid. This makes it possible to prevent the metal such as Cu from being precipitated on the conductive film connected to the N-type portion, which suppresses adjacent conductive films from being short-circuited.

### <Bonding Method>

Next, a bonding method according to an embodiment will be described.

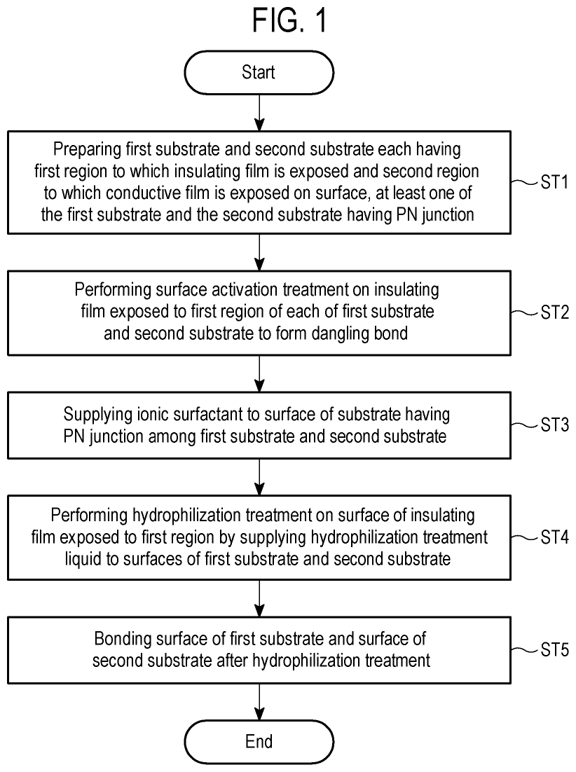

FIG. 1 is a flowchart for explaining the bonding method according to an embodiment. As illustrated in FIG. 1, the bonding method according to the present embodiment includes Operations ST1 to ST5.

In Operation ST1, each of a first substrate and a second substrate whose surface has a first region from which an insulating film is exposed and a second region from which a conductive film is exposed is prepared. At least one of the first substrate or the second substrate has a PN junction. In Operation ST2, a surface activation treatment is performed on the insulating film exposed from the first region of each of the first substrate and the second substrate to form a dangling bond. In Operation ST3, an ionic surfactant is supplied to the surface of the at least one of the first substrate or the second substrate which has the PN junction. In Operation ST4, a hydrophilization treatment is performed on the surface of the insulating film exposed from the first region of each of the first substrate and the second substrate by supplying a hydrophilization treatment liquid to the surfaces of the first substrate and the second substrate. In Operation ST5, the surface of the first substrate and the surface of the second substrate which are subjected to the hydrophilization treatment are bonded to each other.

Hereinafter, a specific description will be given.

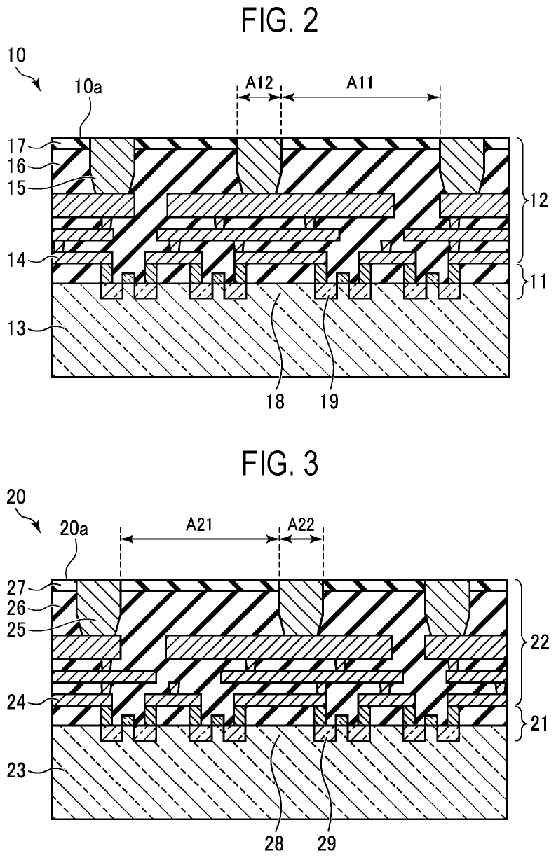

The first substrate and the second substrate prepared in Operation ST1 have structures as illustrated in, for example, FIG. 2 and FIG. 3, respectively.

As illustrated in FIG. 2, a first substrate 10 includes a calculation portion 11 and a wiring layer 12. The calculation portion 11 is formed to include a part of a base substrate 13. The calculation portion 11 includes, for example, a semiconductor device such as a transistor. The base substrate 13 is, for example, a semiconductor wafer. The base substrate 13 has, for example, a channel region 18 and a diffusion region 19 on a surface portion thereof.

The wiring layer 12 is, for example, a multilayer wiring. The wiring layer 12 includes a wiring 14, an electrode pad 15, a first insulating film 16, and a second insulating film 17. The wiring 14 is provided in multiple layers and is electrically connected to the calculation portion 11. The electrode pad 15 is provided on the wiring 14 that is spaced apart farthest from the base substrate 13. The electrode pad 15 is electrically connected to the wiring 14 and is electrically connected to the calculation portion 11 via the wiring 14. An upper surface of the electrode pad 15 is exposed. The wiring 14 and the electrode pad 15 are formed of, for example, copper (Cu). The wiring 14 and the electrode pad 15 may be aluminum (Al), silver (Ag), or gold (Au) in addition to copper (Cu). The first insulating film 16 is, for example, an interlayer insulating film that fills between the wirings 14 multilayered as above. The first insulating film 16 is not particularly limited but may include, for example, a SiO film, a SiN film, a SiOC film, a SiON film, or a SiOCN film. In addition, an atomic ratio of elements in each film is optional. The interlayer insulating film may be a low-dielectric constant (low-k) film such as a SiOC film, a SiON film, or a SiOCN film. The second insulating film 17 is provided on the first insulating film 16. An upper surface of the second insulating film 17 is exposed. The upper surface of the second insulating film 17 is flush with, for example, the upper surface of the electrode pad 15. The second insulating film 17 is not particularly limited but may include, for example, a SiO film, a SiN film, a SiOC film, a SiON film, or a SiOCN film. The upper surface of the first insulating film 16 may be exposed to flush with the electrode pad 15 without providing the second insulating film 17.

The wiring layer 12 may further include, for example, a barrier film provided between the wiring 14 and the first insulating film 16. The wiring layer 12 may further include, for example, a barrier film provided between the electrode pad 15 and the first insulating film 16. The barrier film suppresses metal from diffusing from the wiring 14 and the electrode pad 15 to the first insulating film 16. The barrier film is not particularly limited but is, for example, a TaN film or a TiN film. An atomic ratio of Ta to N in the TaN film and an atomic ratio of Ti to N in the TiN film are optional.

The first substrate 10 has a surface 10a. The surface 10a has a first region A11 from which the second insulating film 17 is exposed and a second region A12 from which the electrode pad 15 is exposed. The second insulating film 17 is an example of the insulating film, and the electrode pad 15 is an example of the conductive film.

A second substrate 20 has, for example, substantially the same configuration as the first substrate 10. As illustrated in FIG. 3, the second substrate 20 includes a calculation portion 21 and a wiring layer 22. The calculation portion 21 is formed to include a part of a base substrate 23. A surface portion of the base substrate 23 has, for example, a channel region 28 and a diffusion region 29 to which a wiring 24 is connected.

The wiring layer 22 is, for example, a multilayer wiring. The wiring layer 22 has the wiring 24, an electrode pad 25, a first insulating film 26, and a second insulating film 27. The electrode pad 25 is made of, for example, the same material as the electrode pad 15.

The second substrate 20 has a surface 20a. The surface 20a has a first region A21 from which the second insulating film 27 is exposed and a second region A22 from which the electrode pad 25 is exposed. The second insulating film 27 is an example of the insulating film, and the electrode pad 25 is an example of the conductive film.

At least one of the first substrate 10 or the second substrate 20 includes the PN junction. For example, the channel region 18 and the diffusion region 19 of the first substrate 10 of FIG. 2 may form the PN junction, the channel region 28 and the diffusion region 29 of the second substrate 20 of FIG. 3 may form the PN junction, or both may form the PN junction. As a specific example, the channel region 18 of the first substrate 10 may be a P-channel and the diffusion region 19 of the first substrate 10 may be an N-well as an N-type portion, the channel region 28 of the second substrate 20 may be a P-channel and the diffusion region 29 of the second substrate 20 may be an N-well as an N-type portion, or the channel region 18 of the first substrate 10 may be a P-channel, the diffusion region 19 of the first substrate 10 may be an N-well as an N-type portion, the channel region 28 of the second substrate 20 may be a P-channel, and the diffusion region 29 of the second substrate 20 may be an N-well as an N-type portion.

Operations ST2 to ST4 are performed as pretreatment for bonding the insulating films when bonding the first substrate 10 and the second substrate 20 to each other.

Among these Operations, Operation ST2 and Operation ST4 are processes for hydrophilizing the surfaces of the second insulating films 17 and 27, which are insulating films.

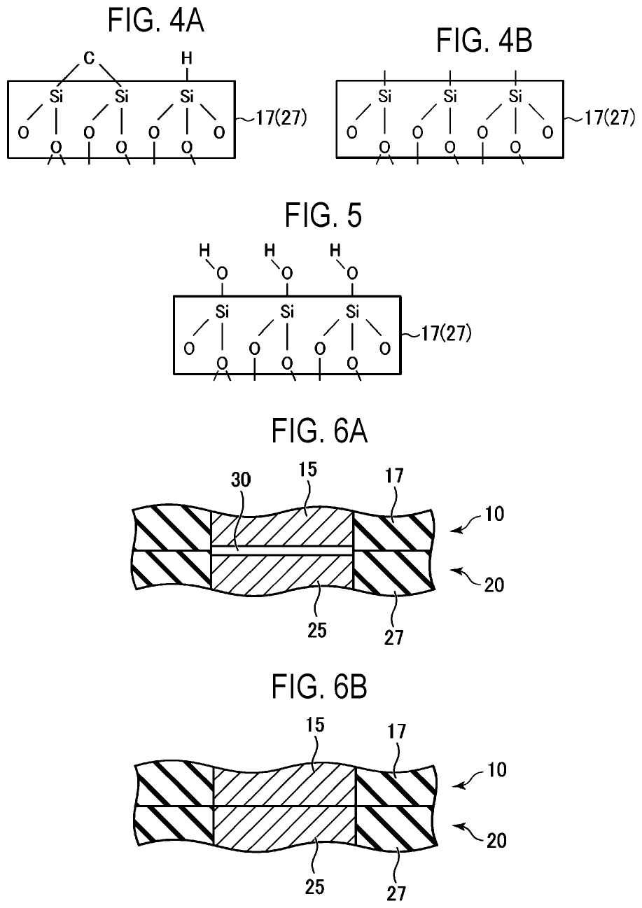

In an initial state as illustrated in FIG. 4A, the surfaces of the second insulating films 17 and 27 exposed from the first regions A11 and A21 of the first substrate 10 and the second substrate 20 are terminated by, for example, H or C. In order to bond the insulating films together, the surfaces of the insulating films need to be terminated by OH groups. Thus, in Operation ST2, the surface activation treatment is first performed on the first regions A11 and A21 (the surfaces of the second insulating films 17 and 27). Then, as illustrated in FIG. 4B, H or C is removed to form the dangling bond.

As the surface activation treatment, for example, plasma-based processing may be exemplified. The plasma-based surface activation treatment may be performed by applying, for example, plasma generated using a N₂ gas, an Ar gas, or the like to the surface of the insulating film. This treatment may be performed by, for example, winding a radio-frequency coil around a nozzle that discharges the gas to the substrate and irradiating the surface of the substrate with plasma of the gas discharged from the nozzle. This plasma may be atmospheric plasma.

In Operation ST4, after performing the surface activation treatment, the hydrophilization treatment is performed on the surfaces of the second insulating films 17 and 27 exposed from the first regions A11 and A21 by supplying the hydrophilization treatment liquid to the surface of the first substrate 10 and the surface of the second substrate 20. Specifically, as illustrated in FIG. 5, the hydrophilization treatment may be performed by supplying the hydrophilization treatment liquid to the surface of the first substrate 10 and the surface of the second substrate 20 such that the OH groups are combined to the dangling bond formed on the surfaces of the insulating films (the second insulating film 17 and 27) in Operation ST2 to form OH termination. In addition, the surfaces of the substrates may be cleaned by the hydrophilization treatment liquid.

A method of supplying the hydrophilization treatment liquid to the first substrate and the second substrate is not particularly limited but may use, for example, a method of forming a liquid film by supplying the hydrophilization treatment liquid to the surface of the substrate while rotating the substrate. After the hydrophilization treatment liquid is supplied, the hydrophilization treatment liquid is removed from the substrate. For example, the hydrophilization treatment liquid may be removed by shaking off the hydrophilization treatment liquid remaining on the substrate while rotating the substrate.

As the hydrophilization treatment liquid, pure water or CO₂ water (carbonated water) obtained by dissolving CO₂ in the pure water may be used. By using the CO₂ water as the hydrophilization treatment liquid, the conductive film (e.g., the Cu film) may be slightly etched. This makes it possible to cope with thermal expansion of the conductive film during the hybrid bonding in which the insulating film and the conductive film are simultaneously bonded to each other. That is, during the hybrid bonding between the first substrate 10 and the second substrate 20, the conductive films are bonded to each other through mutual diffusion of metals in the conductive films due to heating, which will be described later. In this case, precision may be reduced due to thermal expansion of the conductive films. When the CO₂ water is used as the hydrophilization treatment liquid, only the electrode pads 15 and 25 (e.g., the Cu films), which are the conductive films, may be slightly etched. Thus, as illustrated in FIG. 6A, when the first substrate 10 and the second substrate 20 are aligned to each other for the subsequent hybrid bonding, a gap 30 may be generated between the electrode pad 15 and the electrode pad 25, which are the conductive films. When the heating is performed in this state, as illustrated in FIG. 6B, the electrode pad 15 and the electrode pad 25 thermally expand and come into contact with each other to fill the gap 30. Thus, the thermal expansion may be absorbed.

The process of supplying the ionic surfactant to the surface of the at least one of the first substrate and the second substrate having the PN junction (Operation ST3) is performed before supplying the hydrophilization treatment liquid in Operation ST4 or parallel to the supply of the hydrophilization treatment liquid. Operation ST3 is performed to suppress the conductive films from being short-circuited when metals (e.g., Cu), which constitute the conductive films (for example, the electrode pads) are precipitated on the conductive films through plating reaction.

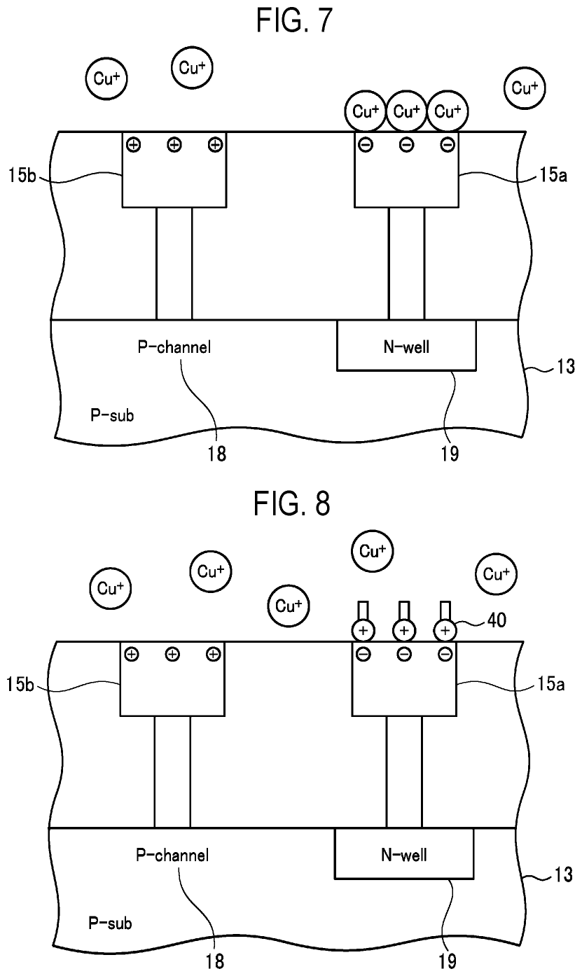

Specifically, in the case in which the PN junction presents in the electronic circuit element in the substrate, for example, the first substrate 10 illustrated in FIG. 2 will be described as an example. As illustrated in FIG. 7, a case in which the channel region 18 is a P-channel, the diffusion region 19 is an N-well as an N-type portion, an electrode pad 15a is connected to the N-well via a wiring, and an electrode pad 15b is connected to the P-channel via a wiring, is considered. In this case, as illustrated in FIG. 7, in a state in which metal ions (for example, Cu ions) from the electrode pads 15a and 15b are dissolved in the hydrophilization treatment liquid, the metal ions (Cu ions) are precipitated as metals (Cu) on the electrode pad 15a connected to the N-well via the wiring by electrolytic plating reaction based on an electromotive force of the PN junction. In this case, the metals (Cu) thus precipitated on the adjacent electrode pads 15a may come into contact with each other so that the adjacent electrode pads 15a may be short-circuited.

In particular, when the first substrate 10 and the second substrate 20 are processed in the presence of light, the electromotive force due to the light is also generated. As a result, the precipitation of the metal (Cu) on the electrode pad 15, which is the conductive film, becomes more significant. In addition, when the hydrophilization treatment liquid is the CO₂ water, since the electrode pad (Cu) 15 as the conductive film is etched, the amount of metal ions (Cu ions) in the liquid increases. Thus, the precipitation of the metal (Cu) on the electrode pad 15 as the conductive film further increases.

Therefore, in Operation ST3, prior to the supply of the hydrophilization treatment liquid in Operation ST4 or parallel to the supply of the hydrophilization treatment liquid in Operation ST4, the ionic surfactant, which is a liquid, is supplied to the surfaces of the first substrate and the second substrate. The ionic surfactant is adsorbed onto the electrode pad 15, which is the conductive film, or adsorbed onto the metal ions (Cu ions) in the hydrophilization treatment liquid, thereby suppressing the precipitation of the metal (Cu) on the electrode pad 15, which is the conductive film.

As the ionic surfactant, a cationic surfactant and an anionic surfactant may be used.

The cationic surfactant is a surfactant having a cationic hydrophilic group. As illustrated in FIG. 8, a cationic surfactant 40 is selectively adsorbed onto the electrode pad 15a on the side of the N-well (the diffusion region 19), which has a negative charge due to the electromotive force generated by the PN junction, and is not adsorbed onto the electrode pad 15b on the side of the P-channel (the channel region 18). Specifically, a hydrophilic group of the cationic surfactant 40 is adsorbed onto the electrode pad 15a having the negative charge. As a result, the electrode pad 15a becomes electrically neutral, and an organic chain of the cationic surfactant 40 physically blocks the metal ions (Cu ions) from reaching the electrode pad 15a having the negative charge. Thus, the precipitation of the metal (Cu) on the electrode pad 15a having the negative charge is suppressed.

As the cationic surfactant, for example, a quaternary ammonium-based cationic surfactant may be used. Examples of the quaternary ammonium-based cationic surfactant may include a dialkyldimethylammonium salt, an ester-type dialkylammonium salt, and an alkyltrimethylammonium salt, and the like.

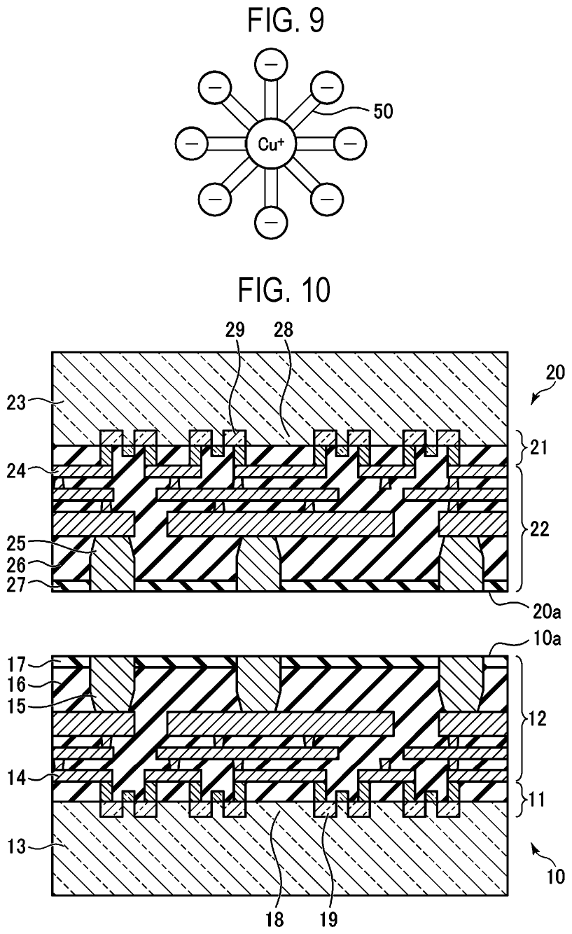

The anionic surfactant is a surfactant having an anionic hydrophilic group. As illustrated in FIG. 9, an anionic surfactant 50 captures the metal ions (Cu ions) in the hydrophilization treatment liquid to electrically neutralize the metal ions. As a result, the precipitation of the metal ions (Cu ions) onto the electrode pad 15a having the negative charge is suppressed.

As the anionic surfactant, for example, a linear alkylbenzene-based anionic surfactant such as a linear alkylbenzene sulfonate, or a higher alcohol-based anionic surfactant such as an alkyl ether sulfuric acid ester salt may be used.

A method of supplying the ionic surfactant to the first substrate and/or the second substrate is not particularly limited but, for example, a method of forming a liquid film by supplying the ionic surfactant to the surface of the substrate while rotating the substrate may be employed. In addition, when the supply of the ionic surfactant is performed parallel to the supply of the hydrophilization treatment liquid in Operation ST4, the ionic surfactant and the hydrophilization treatment liquid may be simultaneously supplied to the first substrate and/or the second substrate. Even in this case, the method of forming the liquid film by supplying the ionic surfactant and the hydrophilization treatment liquid to the surface of the substrate while rotating the substrate may be employed.

The ionic surfactant needs to be removed after supplying the hydrophilization treatment liquid to perform the hydrophilization treatment. However, since both the cationic surfactant and the anionic surfactant have hydrophilic groups, they may be removed by pure water. In a case in which the pure water or the CO₂ water is used as the hydrophilization treatment liquid, when the liquid film of the pure water or the CO₂ water formed on the substrate surface is removed by shaking off or the like after the hydrophilization treatment, the cationic surfactant and the anionic surfactant may also be removed. Alternatively, when the pure water or the CO₂ water is removed by shaking off or the like after the hydrophilization treatment, a rinsing liquid such as pure water may be supplied.

In the process of bonding the first substrate and the second substrate after the hydrophilization treatment in Operation ST5, the surface of the first substrate and the surface of the second substrate are aligned to each other and are pressed against each other by heat and pressure applied thereto.

Specifically, as illustrated in FIG. 10, the surface 10a of the first substrate 10 and the surface 20a of the second substrate 20 are held to face each other, and the first substrate 10 and the second substrate 20 are aligned to each other. Such an alignment is performed by facing the electrode pad 15 and the electrode pad 25 as the conductive films each other, and facing the second insulating film 17 and the second insulating film 27 as the insulating films each other.

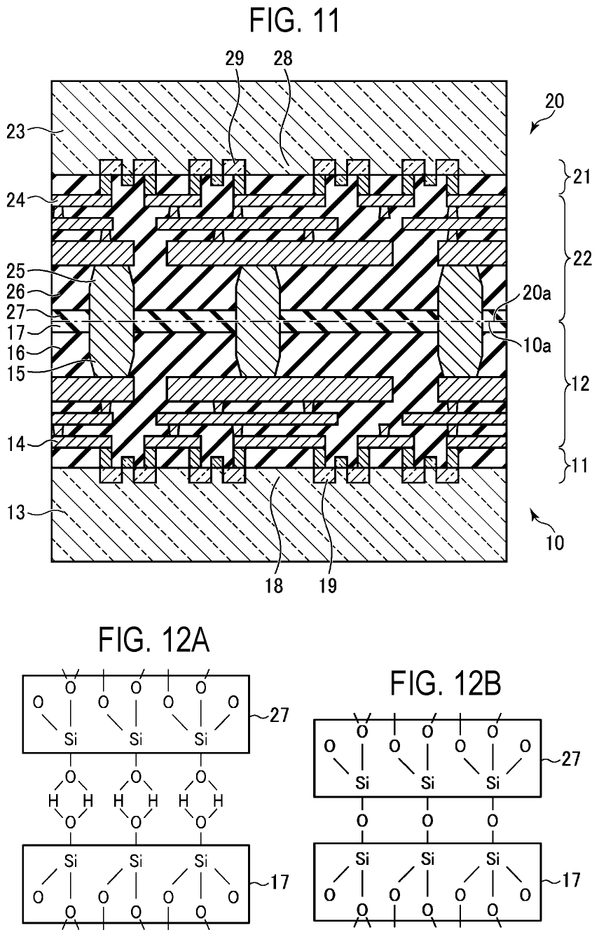

Next, while heating the first substrate 10 and the second substrate 20, as illustrated in FIG. 11, the surface 10a of the first substrate 10 and the surface 20a of the second substrate 20 are brought into contact with each other and are pressed against each other by the pressure applied thereto. As a result, the surface 10a of the first substrate 10 and the surface 20a of the second substrate 20 are bonded to each other. In this case, the electrode pad 15 and the electrode pad 25 are bonded to each other by the diffusion of metals (for example, Cu) in the electrode pads. As illustrated in FIG. 12A, the second insulating film 17 and the second insulating film 27 are coupled to each other by the bonding of OH groups of the surfaces 10a and 20a. Subsequently, as illustrated in FIG. 12B, coupling of Si—O—Si is formed by dehydration condensation so that the second insulating film 17 and the second insulating film 27 are bonded to each other. In this case, a heating temperature may be about 100 to 400 degrees C. and the pressure may be about 100 to 300 g.

An atmosphere of the bonding process in Operation ST5 is not particularly limited. The bonding process may be performed in a vacuum atmosphere to suppress oxidation and corrosion of the electrode pad 15 and the electrode pad 25, which are the conductive films.

### <Bonding Apparatus>

Next, a bonding apparatus for performing the bonding method according to an embodiment will be described.

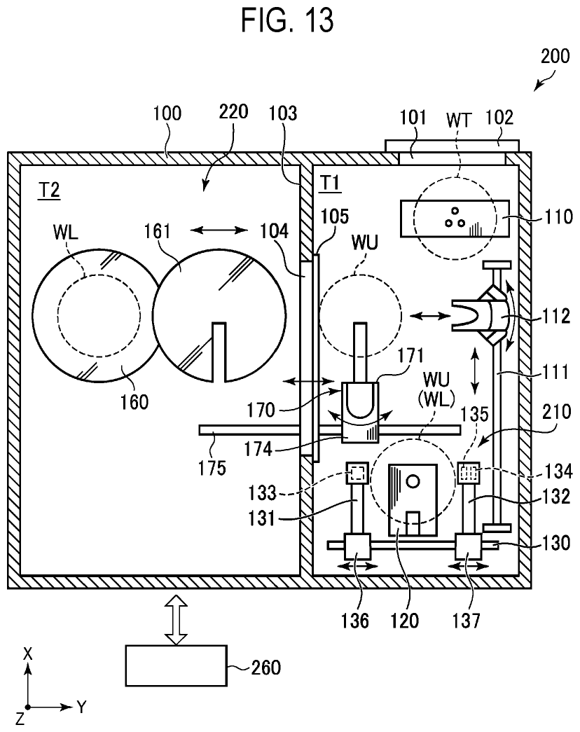

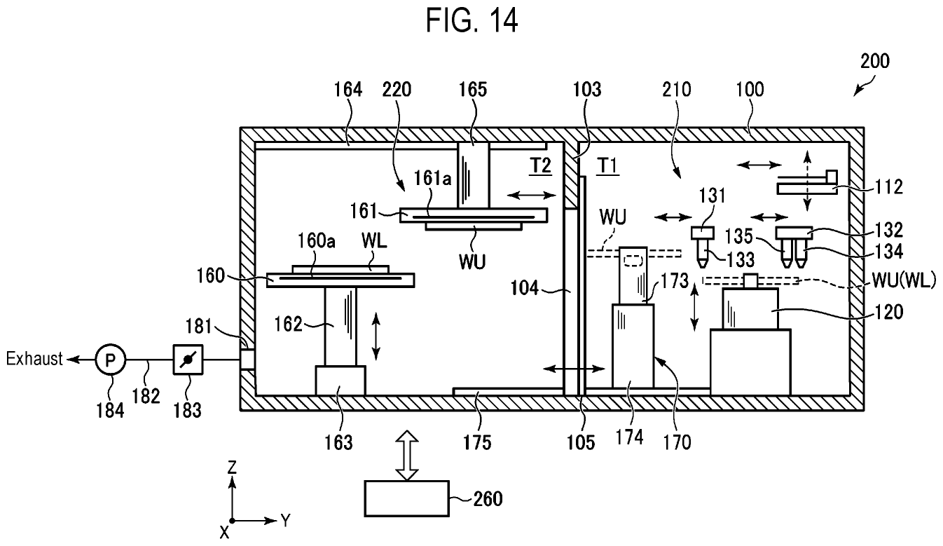

FIG. 13 is a transverse cross-sectional view illustrating an example of the bonding apparatus for performing the bonding method according to an embodiment, and FIG. 14 is a longitudinal cross-sectional view illustrating the bonding apparatus. In FIG. 13, an upper side is a positive side in an X-axis direction, and a lower side is a negative side in the X-axis direction. In FIGS. 13 and 14, a left side is a negative side in a Y-axis direction, and a right side is a positive side in the Y-axis direction. In FIGS. 13 and 14, a substrate WU refers to a substrate arranged on the upper side, a substrate WL refers to a substrate arranged on the lower side, and a bonded substrate WT refers to a substrate formed by overlapping the upper substrate WU and the lower substrate WL. In addition, these substrates may be collectively referred to simply as a substrate.

A bonding apparatus 200 includes a processing container 100 whose interior is hermetically sealable. As illustrated in FIG. 13, a loading/unloading port 101 for transferring the upper substrate WU, the lower substrate WL, and the bonded substrate WT therethrough is provided in a side surface of the processing container 100 in the positive X-axis direction. The loading/unloading port 101 is opened and closed by an opening/closing shutter 102.

The interior of the processing container 100 is partitioned into a pretreatment region T1 and a bonding region T2 by an inner wall 103. In the pretreatment region T1, a transferer configured to transfer the substrate and a pretreater 210 configured to perform the pretreatment on the substrate before bonding are provided. Although not illustrated in FIG. 13, the pretreater 210 includes an activation treater 230, an ionic surfactant supply 240, and a hydrophilization treatment liquid supply 250, which will be described later. The loading/unloading port 101 is formed in the side surface of the processing container 100 in the pretreatment region T1. A loading/unloading port 104 for transferring the upper substrate WU, the lower substrate WL, and the bonded substrate WT is formed in the inner wall 103. The loading/unloading port 104 is opened and closed by a gate valve 105.

A transition 110 for placing loading the upper substrate WU, the lower substrate WL, and the bonded substrate WT thereon is provided in the pretreatment region T1 in the positive X-axis direction. The transition 110 may be formed, for example, in two stages, and may simultaneously place two of the upper substrate WU, the lower substrate WL, and the bonded substrate WT thereon.

In the pretreatment region T1, a substrate transfer body 112 which is movable along a transfer path 111 extending in the X-axis direction is provided. The substrate transfer body 112 is movable in a vertical direction (Z-axis direction) and rotatable about a vertical axis to transfer the upper substrate WU, the lower substrate WL, and the bonded substrate WT inside the pretreatment region T1 or between the pretreatment region T1 and the bonding region T2.

A position adjusting mechanism 120 for rotating the upper substrate WU and the lower substrate WL while supporting them is provided in the pretreatment region T1 in the negative X-axis direction. The position adjusting mechanism 120 is configured to adjust a horizontal orientation of the substrate and rotate the substrates supported as above during a surface activation treatment, an ionic surfactant supply treatment, and a hydrophilization treatment, which will be described later.

A rail 130 extending in the Y-axis direction is provided in the position adjusting mechanism 120 in the pretreatment region T1 in the negative X-axis direction. The rail 130 is provided, for example, from an outer side of the position adjusting mechanism 120 in the negative Y-axis direction to an outer side of the position adjusting mechanism 120 in the positive Y-axis direction. For example, two nozzle arms 131 and 132 are movably mounted on the rail 130.

The nozzle arm 131 supports a plasma nozzle 133, which is a part of the activation treater 230. The nozzle arm 131 is movable on the rail 130 by a nozzle drive 136. As a result, the plasma nozzle 133 is movable from an outer side of the position adjusting mechanism 120 in the positive Y-axis direction to upper sides of the upper substrate WU and the lower substrate WL held by the position adjusting mechanism 120. The nozzle arm 131 may be raised and lowered by the nozzle drive 136 and adjust a height of the plasma nozzle 133.

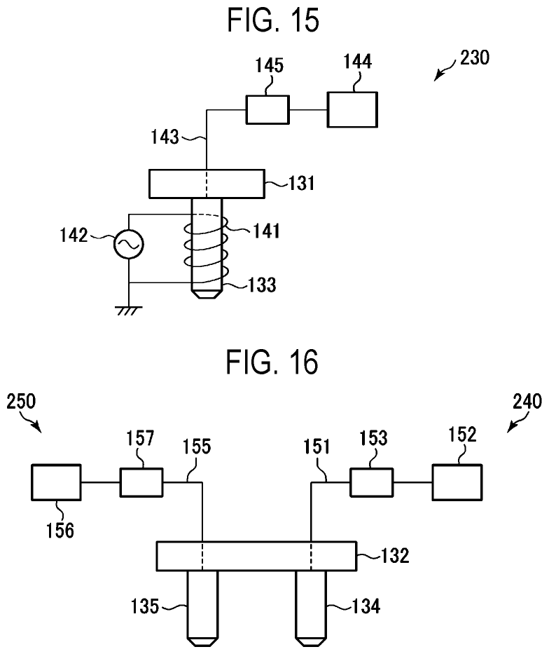

As illustrated in FIG. 15, the activation treater 230 includes the plasma nozzle 133, a coil 141, a radio-frequency power source 142, a gas supply pipe 143, a gas source 144, and a supply device group 145. The coil 141 is wound around the plasma nozzle 133. The radio-frequency power source 142 is connected to the coil 141. The gas supply pipe 143 is connected to the plasma nozzle 133. The gas source 144 is connected to the gas supply pipe 143. Further, an activation treatment gas, such as a N₂ gas or an Ar gas, is supplied from the gas source 144 to the plasma nozzle 133. The supply device group 145 includes a valve, a flow rate regulator, or the like provided in the gas supply pipe 143. The gas supplied from the gas source 144 to the plasma nozzle 133 via the gas supply pipe 143 is plasmarized by radio-frequency power supplied from the radio-frequency power source 142 to the coil 141. Plasma thus generated is supplied to the surface of the substrate, which is supported by the position adjusting mechanism 120 and located below the plasma nozzle 133, to perform the surface activation treatment.

The nozzle arm 132 supports an ionic surfactant nozzle 134, which is a part of the ionic surfactant supply 240, and a hydrophilization treatment liquid nozzle 135, which is part of the hydrophilization treatment liquid supply 250. The nozzle arm 132 is movable along the rail 130 by a nozzle drive 137. As a result, the ionic surfactant nozzle 134 and the hydrophilization treatment liquid nozzle 135 is movable from the position adjusting mechanism 120 in the negative Y-axis direction to the upper sides of the upper substrate WU and the lower substrate WL held by the position adjusting mechanism 120. The nozzle arm 132 is capable of being raised and lowered by the nozzle drive 137 to adjust heights of the ionic surfactant nozzle 134 and the hydrophilization treatment liquid nozzle 135. In addition, instead of simultaneously moving the ionic surfactant nozzle 134 and the hydrophilization treatment liquid nozzle 135 while supporting them using the nozzle arm 132, these nozzles may be provided in different arms (driving mechanisms) and controlled to be moved separately.

The ionic surfactant supply 240 and the hydrophilization treatment liquid supply 250 are configured as illustrated in FIG. 16.

The ionic surfactant supply 240 includes the ionic surfactant nozzle 134, an ionic surfactant supply pipe 151, an ionic surfactant source 152, and a supply device group 153. The ionic surfactant supply pipe 151 is connected to the ionic surfactant nozzle 134, and the ionic surfactant source 152 is connected to the ionic surfactant supply pipe 151. Via the ionic surfactant supply pipe 151 and the ionic surfactant nozzle 134, an ionic surfactant is discharged from the ionic surfactant source 152 toward the surfaces of the substrates, which are supported by the position adjusting mechanism 120 and located below the ionic surfactant nozzle 134. The supply device group 153 includes a valve, a flow rate regulator, and the like, which are connected to the ionic surfactant supply pipe 151. The ionic surfactant supply treatment is performed by supplying the ionic surfactant from the ionic surfactant source 152 to the surfaces of the substrates via the ionic surfactant supply pipe 151 and the ionic surfactant nozzle 134 while rotating the substrates supported by the position adjusting mechanism 120.

The hydrophilization treatment liquid supply 250 includes the hydrophilization treatment liquid nozzle 135, a hydrophilization treatment liquid supply pipe 155, a hydrophilization treatment liquid source 156, and a supply device group 157. The hydrophilization treatment liquid supply pipe 155 is connected to the hydrophilization treatment liquid nozzle 135, and the hydrophilization treatment liquid source 156 is connected to the hydrophilization treatment liquid supply pipe 155. Via the hydrophilization treatment liquid supply pipe 155 and the hydrophilization treatment liquid nozzle 135, the hydrophilization treatment liquid is discharged from the hydrophilization treatment liquid source 156 toward the surfaces of the substrates, which are supported by the position adjusting mechanism 120 and located below the hydrophilization treatment liquid nozzle 135. The supply device group 157 includes a valve, a flow rate controller, and the like, which are connected to the hydrophilization treatment liquid supply pipe 155. The hydrophilization treatment is performed by supplying the hydrophilization treatment liquid from the hydrophilization treatment liquid source 156 to the surfaces of the substrates via the hydrophilization treatment liquid supply pipe 155 and the hydrophilization treatment liquid nozzle 135 while rotating the substrates supported by the position adjusting mechanism 120.

A bonding treater 220 is provided in the bonding region T2. The bonding treater 220 includes a lower chuck 160 configured to hold the lower substrate WL placed on an upper surface thereof, and an upper chuck 161 configured to hold the upper substrate WU attracted to a lower surface thereof. The upper chuck 161 is provided above the lower chuck 160. The upper chuck 161 is provided to be horizontally movable and is arranged to face the lower chuck 160. Thus, the lower substrate WL held by the lower chuck 160 and the upper substrate WU held by the upper chuck 161 may be arranged to face each other.

An electrostatic adsorption electrode (not illustrated) electrically connected to a direct current power source (not illustrated) or a suction pipe (not illustrated) communicating with a vacuum pump (not illustrated) is provided inside the lower chuck 160. The lower substrate WL is attracted to and held by the upper surface of the lower chuck 160 by an electrostatic force such as a Coulomb force generated by the electrostatic adsorption electrode or by suction from the suction pipe.

A heater 160a is provided inside the lower chuck 160. The heater 160a heats the lower substrate WL attracted to/held by the lower chuck 160.

A chuck drive 163 is provided below the lower chuck 160 via a shaft 162. The chuck drive 163 is configured to raise and lower the lower chuck 160. The chuck drive 163 may be configured to move the lower chuck 160 in the horizontal direction. The chuck drive 163 may be configured to rotate the lower chuck 160 around a vertical axis.

An electrostatic adsorption electrode (not illustrated) electrically connected to a direct current power source (not illustrated) or a suction pipe (not illustrated) communicating with a vacuum pump (not illustrated) is provided inside the upper chuck 161. The upper substrate WU is attracted to and held by the lower surface of the upper chuck 161 by an electrostatic force such as a Coulomb force generated by the electrostatic adsorption electrode or by suction from the suction pipe.

A heater 161a is provided inside the upper chuck 161. The heater 161a heats the upper substrate WU attracted to/held by the upper chuck 161.

A rail 164 extending along the Y-axis direction is provided above the upper chuck 161. The upper chuck 161 is movable along the rail 164 by a chuck drive 165. The chuck drive 165 is configured to raise and lower the upper chuck 161. The chuck drive 165 may be configured to rotate the upper chuck 161 around a vertical axis.

An inversion mechanism 170, which moves between the pretreatment region T1 and the bonding region T2, is provided inside the processing container 100 to invert the front and back surfaces of the upper substrate WU. The inversion mechanism 170 includes a holding arm 171 for holding the upper substrate WU. A suction pad (not illustrated) for suctioning and holding the upper substrate WU horizontally is provided on the holding arm 171. The holding arm 171 is supported by a drive 173. The drive 173 is configured to rotate the holding arm 171 around a horizontal axis and to extend and contract the holding arm 171 in the horizontal direction. A drive 174 is provided below the drive 173. The drive 174 is configured to rotate the drive 173 around a vertical axis and to raise and lower the drive 173 in the vertical direction. The drive 174 is attached to a rail 175 that extends in the Y-axis direction. The rail 175 extends from the bonding region T2 to the pretreatment region T1. The inversion mechanism 170 is movable between the position adjusting mechanism 120 and the upper chuck 161 along the rail 175 by the drive 174. Further, the configuration of the inversion mechanism 170 is not limited thereto, and may have any configuration as long as it may invert the front and back surfaces of the upper substrate WU. The inversion mechanism may be provided in the substrate transfer body 112, and another transfer mechanism may be provided at the position of the inversion mechanism 170.

An exhaust port 181 is provided in the side surface of the processing container 100 in the bonding region T2. An exhaust passage 182 is connected to the exhaust port 181. A pressure regulating valve 183 and a vacuum pump 184 are sequentially installed in the exhaust passage 182 to constitute an exhaust mechanism. The bonding region T2 may be exhausted by the exhaust mechanism such that the bonding region T2 is maintained in a depressurized atmosphere. Alternatively, the bonding region T2 may be maintained at atmospheric pressure without providing the exhaust mechanism. In this case, the gate valve 105 may be omitted.

The bonding apparatus 200 further includes a controller 260. The controller 260 includes a main controller provided with a CPU (computer), an input device, an output device, a display device, and a memory device. The main controller controls individual constituent elements of the bonding apparatus 200. The main controller of the controller 260 causes the individual constituent elements to execute the above-described bonding method on based on, for example, a process recipe stored in a memory medium of the memory device.

Next, an operation of bonding the upper substrate WU and the lower substrate WL in the bonding apparatus 200 configured as above will be described. The lower substrate WL corresponds to the first substrate 10, and the upper substrate WU corresponds to the second substrate 20.

First, the upper substrate WU is transferred to the bonding apparatus 200. The upper substrate WU is loaded into the pretreatment region T1 of the bonding apparatus 200 via the loading/unloading port 101 by an external transfer mechanism (not illustrated), and is transferred to the position adjusting mechanism 120 by the substrate transfer body 112 via the transition 110.

Next, the nozzle arm 131 is scanned by the nozzle drive 136 to move the plasma nozzle 133 above a central portion of the upper substrate WU supported by the position adjusting mechanism 120. Subsequently, an activation treatment gas is supplied to the plasma nozzle 133 from the gas source 144 via the gas supply pipe 143, and radio-frequency power is supplied to the coil 141 from the radio-frequency power source 142. Then, plasma is irradiated to the surface of the upper substrate WU from the plasma nozzle 133 to perform the surface activation treatment on the insulating film of the upper substrate WU. As a result, the dangling bond is formed on the surface of the insulating film.

Subsequently, the plasma nozzle 133 is returned to its original position, and the nozzle arm 132 is scanned by the nozzle drive 137 to move the ionic surfactant nozzle 134 and the hydrophilization treatment liquid nozzle 135 above the upper substrate WU supported by the position adjusting mechanism 120. Then, in the case in which the upper substrate WU has the PN junction, the ionic surfactant nozzle 134 is positioned above the central portion of the upper substrate WU, and while rotating the upper substrate WU, the ionic surfactant is supplied to the surface of the upper substrate WU from the ionic surfactant nozzle 134. The supplied ionic surfactant is spread over the surface of the upper substrate WU by a centrifugal force and consequently supplied to the entire surface of the upper substrate WU. This suppresses the precipitation of the metal (Cu) on the conductive film (electrode pad). As described above, the cationic surfactant and the anionic surfactant may be used as the ionic surfactant.

Next, the nozzle arm 132 is scanned by the nozzle drive 137 to move the hydrophilization treatment liquid nozzle 135 above the central portion of the upper substrate WU. Subsequently, while rotating the upper substrate WU, the hydrophilization treatment liquid is supplied to the surface of the upper substrate WU from the hydrophilization treatment liquid nozzle 135. The supplied hydrophilization treatment liquid is spread over the surface of the upper substrate WU by the centrifugal force and consequently supplied to the entire surface of the upper substrate WU. As a result, the dangling bond formed on the surface of the insulating film of the upper substrate WU is OH-terminated to become hydrophilic. As described above, the pure water or the CO₂ water may be used as the hydrophilization treatment liquid.

Alternatively, the ionic surfactant and the hydrophilization treatment liquid may be simultaneously supplied to the upper substrate WU from the ionic surfactant nozzle 134 and the hydrophilization treatment liquid nozzle 135.

Thereafter, the horizontal orientation of the upper substrate WU is adjusted by the position adjusting mechanism 120, and the upper substrate WU is delivered from the position adjusting mechanism 120 to the holding arm 171 of the inversion mechanism 170. Subsequently, in the pretreatment region T1, the front and back surfaces of the upper substrate WU are inverted by inverting the holding arm 171. That is, the surface of the upper substrate WU is oriented downward. Next, the inversion mechanism 170 moves toward the upper chuck 161 of the bonding region T2, and the upper substrate WU is delivered from the inversion mechanism 170 to the upper chuck 161. The back surface of the upper substrate WU is attracted to and held by the upper chuck 161. Subsequently, the upper chuck 161 is moved by the chuck drive 165 to a position above the lower chuck 160 and facing the lower chuck 160. Then, the upper substrate WU is on standby on the upper chuck 161 until the lower substrate WL described later is transferred to the bonding apparatus. Further, the inversion of the front and back surfaces of the upper substrate WU may be performed while the inversion mechanism 170 is moving.

Next, the lower substrate WL is transferred to the bonding apparatus 200. The lower substrate WL is loaded into the pretreatment region T1 of the bonding apparatus 200 via the loading/unloading port 101 by the external transfer mechanism (not illustrated), and is transferred to the position adjusting mechanism 120 by the substrate transfer body 112 via the transition 110. Subsequently, the nozzle arm 131 is scanned by the nozzle drive 136 to move the plasma nozzle 133 above the central portion of the lower substrate WL supported by the position adjusting mechanism 120. Next, in the same operation as that performed on the upper substrate WU, plasma is irradiated to the surface of the lower substrate WL from the plasma nozzle 133, and the surface activation treatment is performed on the insulating film of the lower substrate WL. Thus, the dangling bond is formed on the surface of the insulating film.

Subsequently, the plasma nozzle 133 is returned to its original position, and the nozzle arm 132 is scanned by the nozzle drive 137 to move the ionic surfactant nozzle 134 and the hydrophilization treatment liquid nozzle 135 above the lower substrate WL supported by the position adjusting mechanism 120. In the case in which the lower substrate WL has the PN junction, the ionic surfactant nozzle 134 is positioned above the central portion of the lower substrate WL. Like the case of the upper substrate WU, the ionic surfactant is supplied to the surface of the lower substrate WL from the ionic surfactant nozzle 134 while rotating the lower substrate WL.

Next, the nozzle arm 132 is scanned by the nozzle drive 137 to move the hydrophilization treatment liquid nozzle 135 above the central portion of the lower substrate WL. Similarly to the case of the upper substrate WU, the hydrophilization treatment liquid is supplied to the surface of the lower substrate WL from the hydrophilization treatment liquid nozzle 135 while rotating the lower substrate WL.

Alternatively, the ionic surfactant and the hydrophilization treatment liquid may be simultaneously supplied to the lower substrate WL from the ionic surfactant nozzle 134 and the hydrophilization treatment liquid nozzle 135.

Thereafter, a horizontal orientation of the lower substrate WL is adjusted by the position adjusting mechanism 120. Then, the lower substrate WL is transferred to the lower chuck 160 of the bonding region T2 by the substrate transfer body 112, and is attracted to and held by the lower chuck 160. In this case, the back surface of the lower substrate WL is held by the lower chuck 160 so that the surface of the lower substrate WL is oriented upward. Further, a groove (not illustrated) in conformity to a shape of the substrate transfer body 112 may be formed in the upper surface of the lower chuck 160 to avoid interference between the substrate transfer body 112 and the lower chuck 160 when delivering the lower substrate WL.

Next, the loading/unloading port 104 is closed by the gate valve 105, and the bonding region T2 is exhausted and depressurized by the vacuum pump 184. Then, the horizontal positions of the lower substrate WL held by the lower chuck 160 and the upper substrate WU held by the upper chuck 161 are adjusted. Specifically, first, images of the surface of the lower substrate WL and the surface of the upper substrate WU are captured using, for example, a CCD camera. Then, based on the captured images, the horizontal position of the upper substrate WU is adjusted by the upper chuck 161 so that a predetermined reference point (not illustrated) on the surface of the lower substrate WL and a reference point (not illustrated) on the surface of the upper substrate WU coincide with each other. Further, in a case in which the lower chuck 160 is horizontally movable by the chuck drive 163, the horizontal position of the lower substrate WL may be adjusted by the lower chuck 160. Alternatively, relative horizontal positions of the lower substrate WL and the upper substrate WU may be adjusted in both the lower chuck 160 and the upper chuck 161.

Next, the lower chuck 160 is raised by the chuck drive 163 so that the surface of the lower substrate WL held by the lower chuck 160 and the surface of the upper substrate WU held by the upper chuck 161 are brought into contact with each other and pressed against each other. As described above, the lower substrate WL has been heated by the heating mechanism 160a and the upper substrate WU has been heated by the heating mechanism 161a. Thus, due to the heat and the pressure at that time, the upper substrate WU and the lower substrate WL are bonded to each other to form the bonded substrate WT. Specifically, the conductive films (electrode pads) of the upper substrate WU and the lower substrate WL are bonded to each other due to the diffusion of the metals so that the insulating films are bonded to each other due to the dehydration condensation reaction of the OH groups.

The bonded substrate WT formed as above is transferred to the transition 110 by the substrate transfer body 112 and is unloaded from the loading/unloading port 101 by the external transfer mechanism (not illustrated).

### Experimental Example

Next, an experimental example will be described.

In the experimental example, an experimental circuit including a plurality of Cu electrode pads was prepared. On the assumption that the electromotive force is generated by the PN junction and light in a state in which the experimental circuit was immersed in the pure water, the CO₂ water of 2 MSΩcm, and the CO₂ water of 0.2 MΩ cm as the hydrophilization treatment liquid, a voltage of −1 V was applied across the Cu electrode pads for 100 seconds (0 V for one pad and −1 V for the other). As a result, it was found that, in any cases, Cu was precipitated on the Cu electrode pad to which the voltage of −1 V was applied.

In contrast, in the case in which the ester-type dialkyl ammonium salt was added as the cationic surfactant to the pure water, the CO₂ water of 2 MΩ cm, the CO₂ water of 0.2 MΩ cm as the hydrophilization treatment liquid, it was found that, even when the same voltage was applied, no Cu was precipitated on the Cu electrode pad to to which the voltage of −1 V was applied. Even when the linear alkylbenzene sulfonate was added as the anionic surfactant to the same hydrophilization treatment liquid and the same voltage was applied, it was found that no Cu was precipitated on the Cu electrode pad to which the voltage of −1 V was applied.

As described above, it was confirmed that both the cationic surfactant and the anionic surfactant, which are the ionic surfactants, may suppress the precipitation of Cu on the Cu electrode pad by the electrolytic plating reaction based on the PN junction.

According to the present disclosure, there are provided a bonding method and a bonding apparatus which are capable of preventing metals in one conductive film from being precipitated on another conductive film and therefore the conductive films from being short-circuited when bonding surfaces of substrates having insulating films and the conductive films formed thereon

### Other Applications

It should be noted that the embodiments disclosed herein are exemplary in all respects and are not restrictive. The above-described embodiments may be omitted, replaced or modified in various forms without departing from the scope and spirit of the appended claims.

For example, in the above embodiments, as the bonding apparatus, an integrated apparatus has been exemplified in which the pretreater including the activation treater, the ionic surfactant supply, and the hydrophilization treatment liquid supply is arranged in the pretreatment region inside the processing container, and a bonder configured to perform an actual bonding treatment is arranged in the bonding region inside the processing container. However, the present disclosure is not limited to such an integrated apparatus, and an apparatus in which the bonder and the pretreater are provided separately, or an apparatus in which the activation treater, the ionic surfactant supply, and the hydrophilization treatment liquid supply constituting the pretreater are provided separately, may be used.

What is claimed is:

1. A bonding method, comprising:
preparing a first substrate and a second substrate, a surface of each of the first substrate and the second substrate having a first region from which an insulating film is exposed and a second region from which a conductive film is exposed, and at least one of the first substrate or the second substrate having a PN junction;
performing a surface activation treatment on the insulating film exposed from the first region of each of the first substrate and the second substrate;
after the surface activation treatment, performing a hydrophilization treatment on a surface of the insulating film exposed from the first region by supplying a hydrophilization treatment liquid to the surfaces of the first substrate and the second substrate;
after the surface activation treatment, and before the hydrophilization treatment or parallel to the hydrophilization treatment, supplying an ionic surfactant to the surface of the at least one of the first substrate or the second substrate, which has the PN junction; and
bonding the surface of the first substrate and the surface of the second substrate after the hydrophilization treatment.

2. The bonding method of claim 1, wherein the surface activation treatment forms a dangling bond on the surface of the insulating film exposed from the first region of each of the first substrate and the second substrate.

3. The bonding method of claim 2, wherein the surface activation treatment is performed by applying plasma to the surface of the insulating film exposed from the first region of each of the first substrate and the second substrate.

4. The bonding method of claim 1, wherein the hydrophilization treatment liquid is pure water, or CO₂ water obtained by dissolving CO₂ in the pure water.

5. The bonding method of claim 1, wherein the ionic surfactant is a cationic surfactant having a cationic hydrophilic group.

6. The bonding method of claim 5, wherein the cationic surfactant is a quaternary ammonium-based cationic surfactant.

7. The bonding method of claim 6, wherein the quaternary ammonium-based cationic surfactant is any one selected from a group consisting of a dialkyldimethylammonium salt, an ester-type dialkylammonium salt, and an alkyltrimethylammonium salt.

8. The bonding method of claim 1, wherein the ionic surfactant is an anionic surfactant having an anionic hydrophilic group.

9. The bonding method of claim 8, wherein the anionic surfactant is a linear alkylbenzene-based anionic surfactant or a higher alcohol-based anionic surfactant.

10. The bonding method of claim 9, wherein the linear alkylbenzene-based anionic surfactant is a linear alkylbenzene sulfonate, and the higher alcohol-based anionic surfactant is an alkyl ether sulfuric acid ester salt.

11. The bonding method of claim 1, wherein the conductive film includes a metal selected from a group consisting of Cu, Al, Ag, and Au.

12. A bonding apparatus for bonding surfaces of a first substrate and a second substrate, the surface of each of the first substrate and the second substrate having a first region from which an insulating film is exposed and a second region from which a conductive film is exposed, and at least one of the first substrate or the second substrate having a PN junction, the bonding apparatus comprising:
an activation treater configured to perform a surface activation treatment on the insulating film exposed from the first region of each of the first substrate and the second substrate;
a hydrophilization treater configured to perform a hydrophilization treatment on a surface of the insulating film exposed from the first region by supplying a hydrophilization treatment liquid to the surfaces of the first substrate and the second substrate;
an ionic surfactant supply configured to supply an ionic surfactant to the surface of the at least one of the first substrate or the second substrate, which has the PN junction; and
a bonder configured to bond the surface of the first substrate and the surface of the second substrate,
wherein the hydrophilization treater supplies the hydrophilization treatment liquid to the surfaces of the first substrate and the second substrate, which are subjected to the surface activation treatment,
wherein the ionic surfactant supply supplies the ionic surfactant to the surface of the at least one of the first substrate or the second substrate, which has the PN junction and are subjected to the surface activation treatment by the activation treater, before the hydrophilization treatment or parallel to the hydrophilization treatment, and
wherein the bonder bonds the surface of the first substrate and the surface of the second substrate which are subjected to the hydrophilization treatment.
